(19) United States
(12) Patent Application Publication
(10) Pub. No.: US 2009/0103372 A1
(43) Pub. Date: Apr. 23, 2009

(54) HIGH PERFORMANCE HIGH CAPACITY MEMORY SYSTEMS

(75) Inventor: Jeng-Jye Shau, Palo Alto, CA (US)

Correspondence Address: JENG-JYE SHAU, 991 AMARILLO AVE., PALO ALTO, CA, 94303, US

(73) Assignee: UNIRAM TECHNOLOGY INC., Mountain View, CA (US)

(21) Appl. No.: 11/933,556

(22) Filed: Nov. 1, 2007

Related U.S. Application Data
(63) Continuation-in-part of application No. 11/874,914, filed on Oct. 19, 2007.

(51) Int. Cl. G11C 7/10; G06F 1/16; H01S 4/00

(52) U.S. Cl. 365/189.02; 29/592.1

(57) ABSTRACT

The present invention provides memory system architectures developed to increase the capacity of memory systems. Typically applications including the main memory of computers. Memory systems of the present invention can achieve capacities larger than prior art systems by one or two orders of magnitudes without significant degradation in performance while using system interfaces that are compatible with existing memory systems with no or minimal modifications.

This application is a continuation-in-part application of previous patent application with a Ser. No. 11/874,914 with the same title and filed by the applicant of this invention on Oct. 19, 2007.

### BACKGROUND OF THE INVENTION

The present invention relates to structures and methods designed to increase the capacity of high performance memory systems.

The present invention is applicable to most types of memories such as dynamic random access memory (DRAM), static random access memory (SRAM), nonvolatile memories, etc. Among the wide varieties of possible applications, the most well known applications are the main memory in computers. We will focus on computer main memory using double data rate version 2 (DDR2) dynamic random access memories (DRAM) as examples to demonstrate the basic principles of the present invention. The scope of the present invention is certainly not limited to particular types of memory or particular types of applications used in our examples.

A “memory system” defined in this patent application is board level circuits supporting memory operation of memory chips. A “memory module” is defined as a sub-circuit of a memory system. A “system level signal” is defined as an electrical signal used to communicate with circuits external to a memory system. A “chip level signal” is defined as an electrical signal used to communicate with memory chips.

It is well known that the performance of a computer is strongly dependent on both the performance as well as the capacity of its main memory. Ideally, a computer wants to have high performance system memory at as large capacity as possible. In reality, high performance and high capacity have conflicting requirements that can become limiting factors. We will discuss key factors on those limitations using typical personal computer memory systems as examples.

The most common memory chip used for computer system memory is DRAM. Table 1 lists typical chip level interface signals for a current art 1 G (2³⁰) bit DDR2 synchronized DRAM integrated circuit chip.

TABLE 1
Standard 1G-bit DDR2 DRAM Interface signals

| Name | Type | Descriptions |
|---|---|---|
| DQ0-DQ7 | In/out | 8-bit data Bidirectional bus |
| DQS, DQS# | In/out | Bidirectional data strobe, may include |
| | | RDQS, RDQS# |
| DM | input | Input data mask |
| A0-A12 | input | Addresses |
| BA0-BA2 | input | Bank addresses |
| CK, CK# | input | Differential clocks |
| CKE | input | Clock enable |
| CS# | input | Chip select |
| RAS#, CAS#, WE# | input | Command inputs; alone with |
| | | CS# define commands |
| ODT | input | On-die termination |
| Vref | input | Reference voltage |
| VDD, VDDQ, VDDL, | power | Power and ground lines |
| VSS, VSSQ, VSSL | | for core, I/O, and DLL |

DRAM chips are typically mounted on small printed circuit board (PCB) called Single-In-line Memory Module (SIMM) or Dual-In-line Memory Module (DIMM); a DIMM is equivalent to two SIMM modules placed into one PCB utilizing both sides of the circuit board. The SIMM or DIMM memory modules provide the flexibility to expand the capacity of computer main memory. The memory controller in chipset typically has the flexibility to support 8 SIMM or 4 DIMM modules. A personal computer typically starts with one installed DIMM or SIMM module while providing additional empty sockets. A user who wants to improve the performance of computer can insert additional modules into the expandable sockets. To support such expandable memory systems, personal computers typically support a system level memory interface with signals listed in Table 2. Beside DQS and DQS#, DDR2 DRAM may have another set of data strobe RDQS and RDQS#; sometimes only one data strobe DQS is used without using DQS#. We will consider those data strobe signals (DQS, DQS#, RDQS, RDQS#) as part of data signals. The scope of the present invention should not be limited on particular types of data strobes.

TABLE 2
Standard personal computer system memory interface signals

| Name | Type | Descriptions |
|---|---|---|
| DQ0-DQ63 | In/out | 64-bit data Bidirectional bus, supported by eight 8-bit |
| | | data bus. 8 more data (DQ64-DQ71) can be added for |
| | | parity or error correction code (ECC). |
| DQS0-DQS7, | In/out | Bidirectional data strobe, one pair for each 8-bit data |
| DQS0#-DQS7# | | bus. One more pair (DQS8, DQS8#) can be added for |
| | | parity or ECC. Sometimes we may have more data |
| | | strobes (RDQS, RDQS#). |
| DM0-DM7. | input | Input data mask. One for each 8-bit data bus. One |
| | | more (DM8) can be added for parity or ECC. |
| A0-A13 | input | Addresses, may have more or less address bits. |
| BA0-BA2 | input | Bank addresses, may have only two bank address bits. |
| CK, CK# | input | Differential clocks, may have separated clocks for |
| | | different modules |
| CKE0-CKE7 | input | Clock enable, one fore each memory module |
| CS#0-CS#7 | input | Chip select signals, one for each memory module. |
| RAS#, CAS#, WE# | input | Command inputs. |
| ODT0-ODT7 | input | On-die termination, one for each memory module |
| RESET# | input | Reset |
| PAR_IN | input | Parity bit for address and control |
| PAR_ERR | output | Parity error found in address and control |
| SCL, SA0-SA2 | input | EEPROM clock and addresses |
| SDA | In/out | EEPROM data |
| Vref | input | Reference voltage |
| VDD, VDDQ, VDDL, | power | Power and ground lines for core, I/O, and DLL |
| VDDE, VSS, VSSQ, | | |
| VSSL | | |

If we draw all these signals in our figures, the resulting figures will be very busy, making it less clear in demonstrating the key points of the present invention. Therefore, in our figures the interface signals are simplified into two groups, namely data signals and control signals. Data signals (DB) are signals directly related to data transfers while following the same signal transfer protocols, including the data bus (DQ), data strobe (DQS and #DQS), and input data mask (DM) signals. Control signals (CTL) are signals used to determine operation states of the memory chips, including the addresses, bank addresses, clocks signals (CK, CK#, CKE), chip select signal (CS#), and command inputs (RAS#, CAS#, WE#). We will not show DC or slow signals such as power lines, reference voltage signals, EEPROM signals, and on-die-termination signals because those connections are not related to the key factors of the present invention. To facilitate clear understanding of the present invention, there is no need to show those details that are well known to people skilled in the art; we will focus on the key elements related to the present invention—the data and control signals of memory chips. For simplicity, the optional parity/ECC data signals are also not included in our discussion because a person with ordinary skill in the art would understand how to apply the present invention on the parity/ECC signals upon disclosure of our examples. The simplified representations of memory interface signals used in our discussions are listed in Table 3.

TABLE 3
Simplified representation of memory interface signals

| meaning | representation | Corresponding signals in Table 2 |
|---|---|---|
| Data signal bus 1 | DB1 | DQ0-DQ7, DQS0, DQS#0, DM0, may have RDQS0, |
| | | RDQS#0 |
| Data signal bus 2 | DB2 | DQ8-DQ15, DQS1, DQS#1, DM1, may have RDQS1, |
| | | RDQS#1 |
| Data signal bus 3 | DB3 | DQ16-DQ23, DQS2, DQS#2, DM2, may have RDQS2, |
| | | RDQS#2 |
| Data signal bus 4 | DB4 | DQ24-DQ31, DQS3, DQS#3, DM3, may have RDQS3, |
| | | RDQS#3 |
| Data signal bus 5 | DB5 | DQ32-DQ39, DQS4, DQS#4, DM4, may have RDQS4, |
| | | RDQS#4 |
| Data signal bus 6 | DB6 | DQ40-DQ47, DQS5, DQS#5, DM5, may have RDQS5, |
| | | RDQS#5 |
| Data signal bus 7 | DB7 | DQ48-DQ53, DQS6, DQS#6, DM6, may have RDQS6, |
| | | RDQS#6 |
| Data signal bus 8 | DB8 | DQ54-DQ63, DQS7, DQS#7, DM7, may have RDQS7, |
| | | RDQS#7 |
| Control signals | CTL | A0-A13, BA0-BA2, CK, CK#, CS#0-CS#7, CKE0-CKE7, |
| | | RAS#, CAS#, WE# |
| Not shown | | DQ64-DQ71, DQS8, DQS#8, DM8, ODT0-ODT8, |
| | | RESET#, PAR_IN, PAR_ERR, SCL, SA0-SA2, Vref, VDD, |
| | | VDDQ, VDDL, VDDE, VSS, VSSQ, VSSL |

The above representations are used to simplify our figures in order clearly disclose the key features of the present invention; the scope of the present invention should not be limited in particular ways of signal representations. For example, one may want to include ODT0-ODT8 signals in CTL.

Using the simplified representations in Table 3, the architectures of typical prior art memory systems can be illustrated by FIGS. 1(a-c). FIGS. 1(a) is the simplified schematic block diagrams for a typical prior art memory module (MM1). This memory module comprises a plurality of memory chips (M11-M18) that shares the same control signals (CTL). The data signals of memory chips are connected in parallel; the first memory chip (M11) supports data signal bus 1 (DB1); the second memory chip (M12) supports data signal bus 2 (DB2); the third memory chip (M13) supports data signal bus 3 (DB3); the forth memory chip (M14) supports data signal bus 4 (DB4); the fifth memory chip (M15) supports data signal bus 5 (DB5); the sixth memory chip (M16) supports data signal bus 6 (DB6); the seventh memory chip (M17) supports data signal bus 7 (DB7); the eighth memory chip (M18) supports data signal bus 8 (DB8). The width of module level data bus is therefore the combined width of all memory chips (M11-M18) on the same module (MM1). We will call such connection as “parallel data connection” in the following discussions.

A common prior art method to increase the capacity of a memory system is to use DIMM modules instead of SIMM modules. FIG. 1(b) shows the simplified schematic block diagram for a DIMM module. A DIMM module comprises one additional memory module (MM2) that is typically placed on the other side of the same print circuit board used to place the first memory module (MM1). The memory chips (M21-M28) of the second memory module (MM2) are connected in the same way as that of the first memory module (MM1). Since both memory modules (MM1, MM2) share the same data signals (DB1-DB8) in a shared bus structure, each memory module must use different chip select signals (part of CTL but not shown separately in figures for simplicity) to avoid driver conflicts; typically, different modules are also connected to different clock enable signals (not shown). Other than chip enable and clock enable signals, typically all other control signals are the same for all memory modules. The two memory modules (MM1, MM2) on the same DIMM module often can share most of signal lines so that the increase in loading is typically less than twice of a single module. Using DIMM module is therefore an efficient prior art method to increase the capacity of memory systems.

If we want to have larger capacity than a DIMM module, we need to add more memory modules to the system. FIG. 1(c) shows the simplified schematic block diagram for a memory system that has 6 additional memory modules. The memory chips (M31-M38) of the third memory module (MM3) are connected in the same way as that of the first memory module (MM1). The memory chips (M41-M48) of the forth memory module (MM4) are connected in the same way as that of the first SIMM module (MM1). The memory chips (M51-M58) of the fifty memory module (MM5) are connected in the same way as that of the first memory module (MM1). The memory chips (M61-M68) of the sixth memory module (MM6) are connected in the same way as that of the first SIMM module (MM1). The memory chips (M71-M78) of the seventh memory module (MM7) are connected in the same way as that of the first memory module (MM1). The memory chips (M81-M88) of the eighth memory module (MM8) are connected in the same way as that of the first SIMM module (MM1). All the memory modules in the same system share the same data signals (DB1-DB8) in a shared bus structure. Therefore, each memory module must use different chip select signals (part of CTL but not shown separately in figures for simplicity) to avoid driver conflicts; typically, different modules are also connected to different clock enable signals (not shown). Other than chip enable and clock enable signals, typically all other control signals are the same for all memory modules.

The capacity of the memory system in FIG. 1(c) is four times the capacity of the memory system in FIG. 1(b). However, when the number of memory modules is increased, the loading on the shared data signals (DB1-DB8) and control signals (CTL) also increases. The “Loading” on a signal is the non-ideal factors that can slow down signals performances such as leakage currents, parasitic capacitances, inductances, resistances, or termination resistors. The loadings for the system in FIG. 1(c) are about four times that of the system in FIG. 1(b). Increase in loading typically means degradation in performance and/or stability. This problem is especially significant for prior art DDR2 synchronized DRAM with data rate higher than 600 millions of bits per second (MPS) per pin. DDR2 DRAM uses Stub Series Terminated Logic (SSTL) buses with on-chip terminal resistors so that each memory chip (even when it is not active) is sinking currents through terminal resistors, making it impractical to connect large number of prior art memory modules while operating at high performance. It is well known that using multiple DDR2 DIMM modules would degrade performance significantly, especially at data rate higher than 600 millions of bits per second (MPS) per pin. Increasing capacity by adding more and more prior art memory modules is therefore not practical. It is therefore strongly desirable to provide methods that can increase the capacity of a memory system without increasing the loading of data and control signals.

One prior art solution to solve the loading problem is to use phase locked loop (PLL) to generate local clock signals, and use buffers to generate local control signals. Such methods reduce the loading on control signals, but the loading problems in data signals are not solved. One of the most popular examples for this approach is the Register DIMM (RDIMM) approach. An RDIMM uses PLL to generate local clock and use a “register chip” that comprises latches to buffer control signals; the price to pay for RDIMM approach is one additional clock latency, and the RDIMM approach does not solve loading problems in data signals.

Another prior art solution for the loading problem is the JEDEC standard “Fully Buffered DIMM” (FBDIMM) approach. An FBDIMM uses an integrated circuit (IC) chip called “Advanced Memory Buffer (AMB)” to control all the interface signals to all memory chips on the module. The loadings on memory chip data and control signals are therefore completely isolated from other memory modules. FIG. 2(a) is a simplified schematic block diagrams for an FBDIMM (FM1). The memory chips (M11-M18) on the FBDIMM (FM11) are arranged in parallel data connection while the data signals (LD1-LD8) and control signals (LCTL) of the memory chips are internal signals controlled by an advanced memory buffer (AMB1). FIG. 2(b) is a simplified schematic block diagram for prior art AMB. The inputs of an AMB come from south bound signal transfer lanes (SB1 ) that typically comprise 10 pairs of high speed differential signal transfer lines. Currently, each pair of the differential signal transfer lines is capable of transferring signals at 4.8 billion bits per second (GPS). The input signals on SB1 are latched and analyzed by pass-through logic circuits. If the inputs request operations to other FBDIMM, the input signals are passed to the next FBDIMM through another south bound signal transfer lanes (SB2). If the inputs request operations on the same FBDIMM, the input signals are sent to a de-serializer, then to a DRAM interface logic circuitry that translates the input signals into control signals (LCTL) to memory chips. The data (LD1-LD8) signals returned from memory chips on the same module received by the DRAM interface are sent to a serializer. The serializer converts the data into proper format and sends the output data to pass-through and merging (P&M) circuits. The P&M logic circuits transfer outputs through north bound signal transfer lanes (NB1) that typically comprise 14 pairs of high speed differential signal transfer lines. Output signals from other FBDIMM modules from another north bound signal transfer lanes (NB2) are also latched and processed by the P&M circuits before sending to NB1. Those high speed signal transfer lanes (SB1, SB2, NB1, NB2) are synchronized by phase-locked loop (PLL) circuits. FIG. 2(b) is a simplified block diagram emphasizing features related to key points of the present invention. Please refer to the data sheets of existing AMB products such as Intel 6400 or NEC P720901 for further details. Those existing AMB products are typically complex high cost integrated circuits (IC) comprise more than 600 interface signals.

To increase the capacity of an FBDIMM system, multiple FBDIMM modules (FM1-FM8) are connected in daisy-chained bus architecture as illustrated in FIG. 2(c). The system input (SB1 ) is connected to the south bound signal transfer lanes (SB1) of the first module (FM1). The system output is connected to the north bound signal transfer lanes (NB1) of the first module (FM1). The inputs to the second module (FM2) are supported by south bound signal transfer lanes (SB2) that are provided by AMB1 in FM1. The outputs from the module (FM2) are supported by north bound signal transfer lanes (NB2) to AMB1 in FM1. The inputs to the third module (FM3) are supported by south bound signal transfer lanes (SB3) that are provided by AMB2 in FM2. The outputs from the module (FM3) are supported by north bound signal transfer lanes (NB3) to AMB2 in FM2. The inputs to the forth module (FM4) are supported by south bound signal transfer lanes (SB4) that are provided by AMB3 in FM3. The outputs from the module (FM4) are supported by north bound signal transfer lanes (NB4) to AMB3 in FM3. The inputs to the fifth module (FM5) are supported by south bound signal transfer lanes (SB5) that are provided by AMB4 in FM4. The outputs from the module (FM5) are supported by north bound signal transfer lanes (NB5) to AMB4 in FM4. The inputs to the sixth module (FM6) are supported by south bound signal transfer lanes (SB6) that are provided by AMB5 in FM5. The outputs from the module (FM6) are supported by north bound signal transfer lanes (NB6) to AMB5 in FM5. The inputs to the seventh module (FM7) are supported by south bound signal transfer lanes (SB7) that are provided by AMB6 in FM6. The outputs from the module (FM7) are supported by north bound signal transfer lanes (NB7) to AMB6 in FM6. The inputs to the eighth module (FM8) are supported by south bound signal transfer lanes (SB8) that are provided by AMB7 in FM7. The outputs from the module (FM8) are supported by north bound signal transfer lanes (NB8) to AMB7 in FM7. The capacity of the memory system in FIG. 2(c) is the same as that of the memory system in FIG. 1(c) while the loadings on all data and controls signals are about the same of a single module in FIG. 1(a). In addition, the loading on all signals lines remain the same no matter how many FBDIMM modules are connected in the memory system, effectively solving the loading problems. However, the memory access latency is increase by the need to transfer signals serially through the AMBs connected in daisy chain architecture. For example, if we want to access the memory chips in the seventh module (FM7), we need to add 7 south bound signal transfer cycles, 7 north bound signal transfer cycles, plus delays caused by AMB logic processing as the overhead in timing. The worst delay time increases linearly with the number of FBDIMM modules linked in the daisy chain, limiting the capability to increase capacity. In addition, the FBDIMM modules are by far more expensive than conventional memory modules, and they are not compatible with conventional memory interfaces, limiting their application on high cost server or work stations. FBDIMM saves power by isolating memory chips in different modules, but the power consumed by overhead in AMB is significant.

It is therefore highly desirable to provide other solutions that can increase total capacity of memory systems without the drawbacks of existing solutions such as FBDIMM approaches.

This application is a continuation-in-part application of previous patent application with a Ser. No. 11/874,914 (914 application) with the same title and filed by the applicant of this invention on Oct. 19, 2007. While the 914 application had covered key features of this application, further detailed examples were provided in FIGS. 6(a-e). In addition, example methods to reduce package loadings for the present invention are illustrated in FIGS. 7(a-c).

### SUMMARY OF THE INVENTION

The primary objective of this invention is, therefore, to provide high capacity memory systems without increasing the loading of data signals. The other primary objective of this invention is to achieve the above objective with minimum overhead in performance and in cost. Another objective is to achieve the above objectives while using interfaces that are compatible with conventional memory systems. These and other objectives are achieved by using multiplexing to isolate loadings on data signals. The resulting memory systems are capable of achieving high capacity with basically the same performance and power of a single conventional memory. The interface signals also can be compatible with conventional memory systems.

While the novel features of the invention are set forth with particularly in the appended claims, the invention, both as to organization and content, will be better understood and appreciated, along with other objects and features thereof, from the following detailed description taken in conjunction with the drawing.

### BRIEF DESCRIPTION OF THE DRAWINGS

FIGS. 1(a-c) are simplified schematic block diagrams for prior art conventional memory systems;

FIGS. 2(a-c) are simplified schematic block diagrams for prior art FBDIMM systems;

FIG. 3(a) is a simplified schematic block diagram for one example of the Multiplexed Memory Buffer (MMB) module of the present invention;

FIG. 3(b) is a simplified symbolic diagram for the bidirectional multiplexer in FIG. 3(a);

FIG. 3(c) is a simplified schematic block diagram for one example of the MMB memory system of the present invention;

FIG. 4(a) is a simplified schematic block diagram for one example of the Multiplexed Bus Memory Buffer (MBMB) module of the present invention;

FIG. 4(b) is a simplified symbolic diagram for the bidirectional multiplexer in FIG. 4(a); and

FIG. 4(c) is a simplified schematic block diagram for MBMB one example of the memory system of the present invention;

FIG. 5 is a simplified schematic diagram for the circuits connected to one data signal in prior art system;

FIG. 6(a) is an example for the simplified schematic diagram of the circuits connected to one data signal in an MMB system;

FIG. 6(b) is an example for simplified schematic diagram of the circuits connected to one data signal in an MBMB system;

FIGS. 6(c-e) are examples for the branch switches used by the present invention; and

FIGS. 7(a-c) are examples for the methods to reduce package loadings.

### DETAILED DESCRIPTION OF THE INVENTION

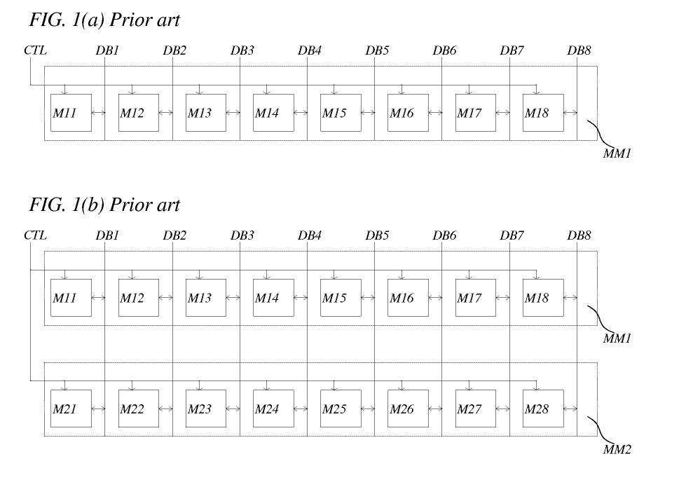

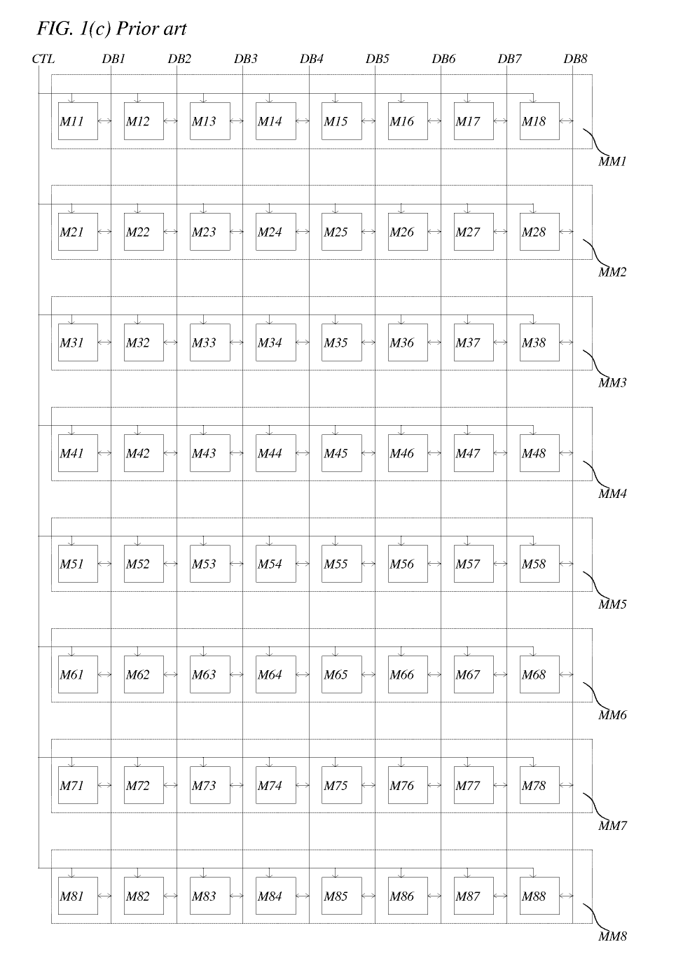

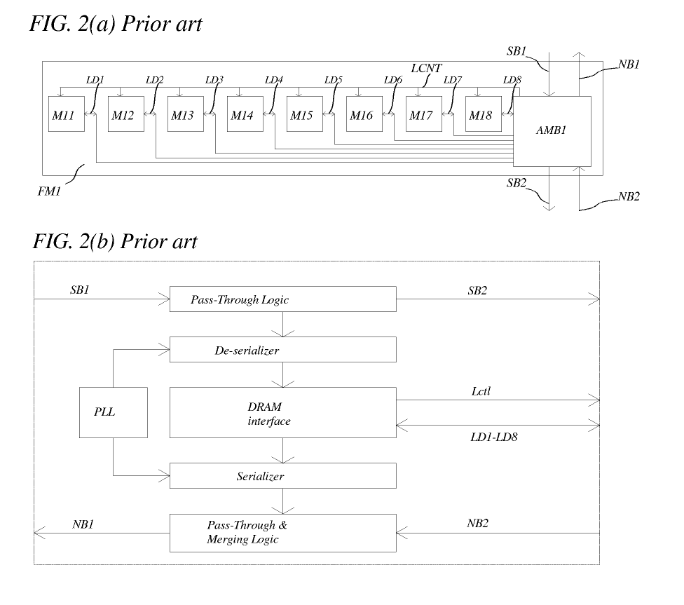

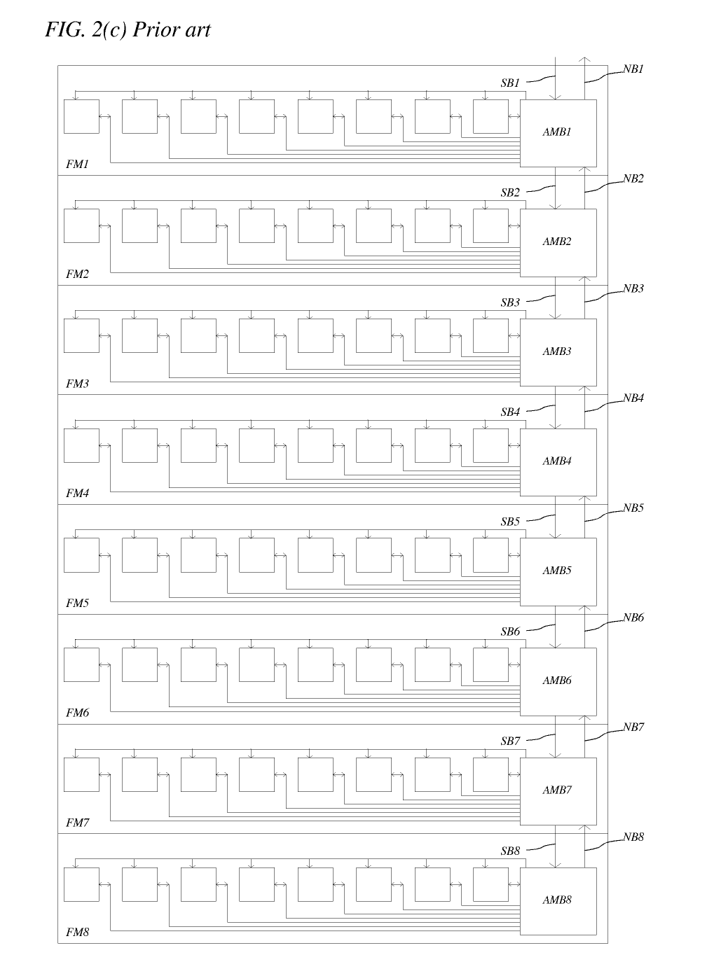

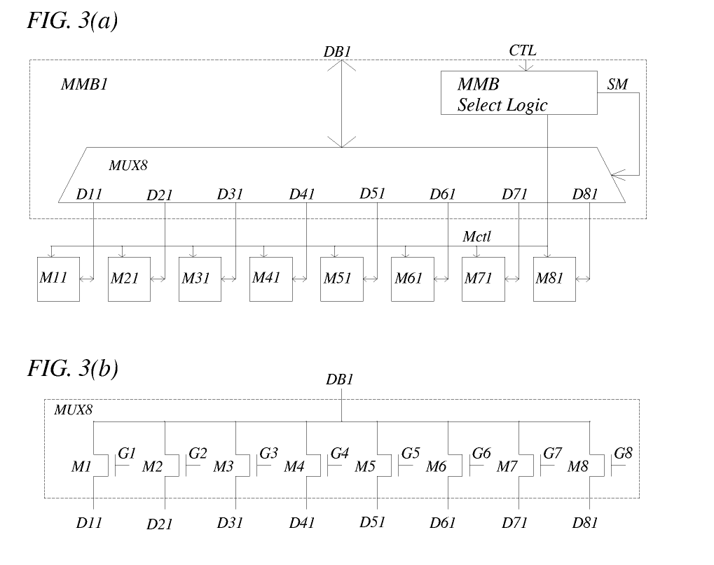

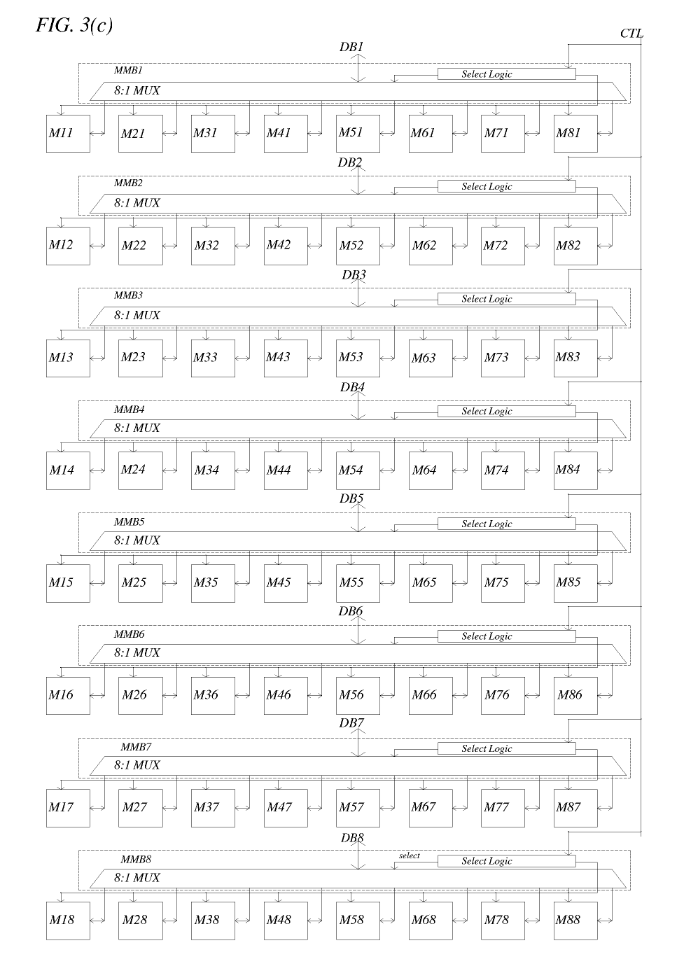

FIG. 3(a) is a simplified schematic block diagram for one example of the Multiplexed Memory Buffer (MMB) module of the present invention. In this example, the MMB memory module (MMB1) comprises 8 memory chips (M11, M21, M31, M41, M51, M61, M71, M81). Comparing to the prior art memory module in FIG. 1(a), the key difference is that the memory chips (M11-M18) in the prior art memory module is arranged in parallel data connection to support a complete set of system data signals (DB1-DB8). In contrast, the memory chips (M11, M21, M31, M41, M51, M61, M71, M81) in memory modules of the present invention is arranged to support a sub set (DB1) of the system data signals, while the first memory chip (M11) supports DB1, the second memory chip (M21) supports DB1, and the eighth memory chip (M81) also supports DB1. In other words, all those memory chips (M11, M21, M31, M41, M51, M61, M71, M81) are arranged to support the same data signals (DB1). The functions of those memory chips are equivalent to the functions of the memory chips in one vertical column of the prior art memory system in FIG. 1(c). Therefore, we call such architecture as “vertical data connection”. We will call the memory chips (M11, M21, M31, M41, M51, M61, M71, M81) in a MMB module as an “MMB group”. “MMB group” is an architecture concept. Chips in an MMB group can be placed in the same printed circuit board or placed in different printed circuit boards. The scopes of the present invention are not limited by the placement of memory chips. Under vertical data connection, at any given time no more than one of the memory chips in the MMB group is allowed to access the system data signal (DB1) under normal operation conditions, making it possible to isolate the loadings of different chips by multiplexing. As shown in FIG. 3(a), the chip level data signals (D11, D21, D31, D41, D51, D61, D71, D81) are connected to the branch entries of bidirectional multiplexers (MUX8), while the system level data signals (DB1) are connected to the root entries of the bidirectional multiplexers (MUX8). FIG. 3(a) uses the symbolic view of a multiplexer to represent a plurality of bi-directional multiplexers because we need one bi-directional multiplexer for each bit of system level data signal (DB1). An MMB select logic circuitry analyzes the system control signal (CTL) and calculates the select signals (SM) for the bidirectional multiplexers (MUX8). This MMB select logic circuitry also serves as buffers to provide chip level control signals (Mct1) to memory chips.

Since data signals of memory chips are typically bi-direction signals (with possible exceptions such as input data masks), the multiplexers (MUX8) in MMB modules actually need to have both multiplexing and de-multiplexing functions. We will call such circuitry as “bidirectional multiplexer” in our discussions. A person with ordinary skill in circuit design would be able to design bidirectional multiplexers in wide varieties of configurations. FIG. 3(b) shows one of the simplest implementations of bidirectional multiplexers useful for applications of the present invention. For this example, the chip level data signals (D11, D21, D31, D41, D51, D61, D71, D81) are connected to the sources of MOS transistors (M1-M8), while the drains of those transistors are all connected to the same system level data signal (DB1). By controlling the gate signals (G1-G8) we can select chip level signals that are allowed to communicate with the system level signal, and isolate the loadings on unselected signals. There are many other ways to implement bidirectional multiplexers. A typical example is to use a pair of p-channel and n-channel pass gate transistors to control one entry. Combinational logic gates also can form equivalent circuitry. The scope of the present invention is not limited by particular implementations of the detailed circuit designs. A “bidirectional multiplexer” defined in the present invention is a circuitry that provides multiplexing as well as de-multiplexing functions for bidirectional signal communication; A “bidirectional multiplexer” has one “root entry” and a plurality of “branch entries”. Using FIG. 3(b) as an example, the transistor sources connected to signals D11, D21, D31, D41, D51, D61, D71, D81 are “branch entries” while the transistor drains connected to signal DB1 is the “root entry” defined in this patent application. In our definition, bidirectional multiplexers used in the present invention must be able to isolate loadings on unselected data signals. “Isolate loadings from a signal” means significantly reduce the effective loading caused by the signal. During normal operation conditions, one or no branch entry of a bidirectional multiplexer is selected to communicate with the “root entry” while the loadings of unselected branch entries are isolated from the root entry. However “bidirectional multiplexer” used for the present invention allows exceptions. For example, we may want to simultaneously select multiple entries in special modes. For another example, during the time to switch from one entry to another entry, we may have both entries turned on for a short period of time. We also want to have the capability to turn off all branch entries. Therefore, unlike the strictly defined logic function of multiplexers, the bidirectional multiplexers used by the present invention does not always guaranteed to have only one selected entry at all time. Different branch entries of a bidirectional multiplexer used by the present invention can be place in the same chip, separated into different chips, or even placed in different printed circuit boards. The scopes of the present invention should not be limited on detailed implementations of the branch entries of the bidirectional multiplexer.

FIG. 3(c) is the simplified schematic block diagram for an MMB memory system that has the same capacity as the prior art memory system in FIG. 1(c). In this example, the memory system comprises 8 MMB modules (MMB1-MMB8). Each MMB module comprises 8 memory chips. Each MMB module is equipped with eight-entry bidirectional multiplexers. Each MMB module support one set of the system level data signals; MMB1 supports DB1, MMB2 supports DB2, MMB3 supports DB3, MMB4 supports DB4, MMB5 supports DB5, MMB6 supports DB6, MMB7 supports DB7, and MMB8 supports DB8. This MMB memory system has the same interface signals, the same capacity, and the same functions as the prior art system in FIG. 1(c); while the loading is equivalent to the loading of one prior art module in FIG. 1(a). Using such architecture is therefore able to support roughly 8 times more capacity than the architecture in FIG. 1(c).

It is well known that a properly controlled bidirectional multiplexer is able to isolate the loadings on unselected branches. The bidirectional multiplexer itself introduces additional loading, but such loading can be designed to be insignificant relative to overall loading. The bidirectional multiplexer also introduced additional delay, but such additional delay can be designed to be insignificant relative to overall delay. The selection logic signal (SM) of the bidirectional multiplexer (MUX8) is determined from system level control signals (CTL) by the MMB Select logic circuitry. The MMB Select logic circuitry can isolate the loading seen by the system level control signals (CTL), but it also introduces additional delays. However, the buffer delay can be designed to be insignificant. In many cases, we may not need to buffer the control signals. The logic function of the MMB Select logic circuitry is similar to DRAM data bus control logic circuits that are well known to the industry. An MMB is certainly by far less complex than a prior art AMB. Upon disclosure of the present invention, a person with ordinary skill in the art will certainly be able to design the MMB in wide varieties of ways so that there is no need to discuss in further details.

The MMB memory systems have many advantages comparing to prior art systems. It has identical functions and identical interface signals (DB1-DB8, CTL) as the prior art system in FIG. 1(c). MMB systems can be fully compatible with existing systems with no or minimal modifications. While the loadings on the data and control signals are equivalent to the loadings of a single module in FIG. 1(a) plus small overhead added by the MMB circuits, the MMB overhead typically can be designed to be insignificant relative to the system loading. Using MMB architectures, it is very common to be able to increase system capacity by 4 to 16 times or more. The timing overhead is typically much less than that of FBDIMM systems. The MMB systems are by far more cost efficient than prior art AMB systems. The power consumed by MMB systems is by far less than prior art systems with equivalent capacities.

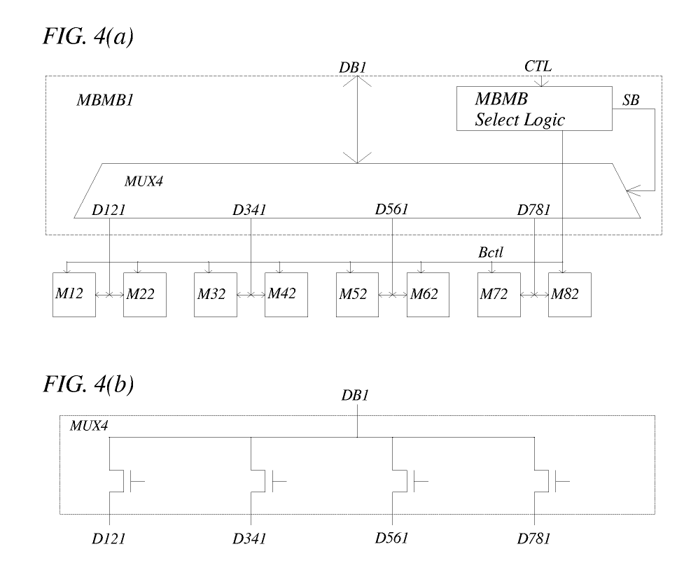

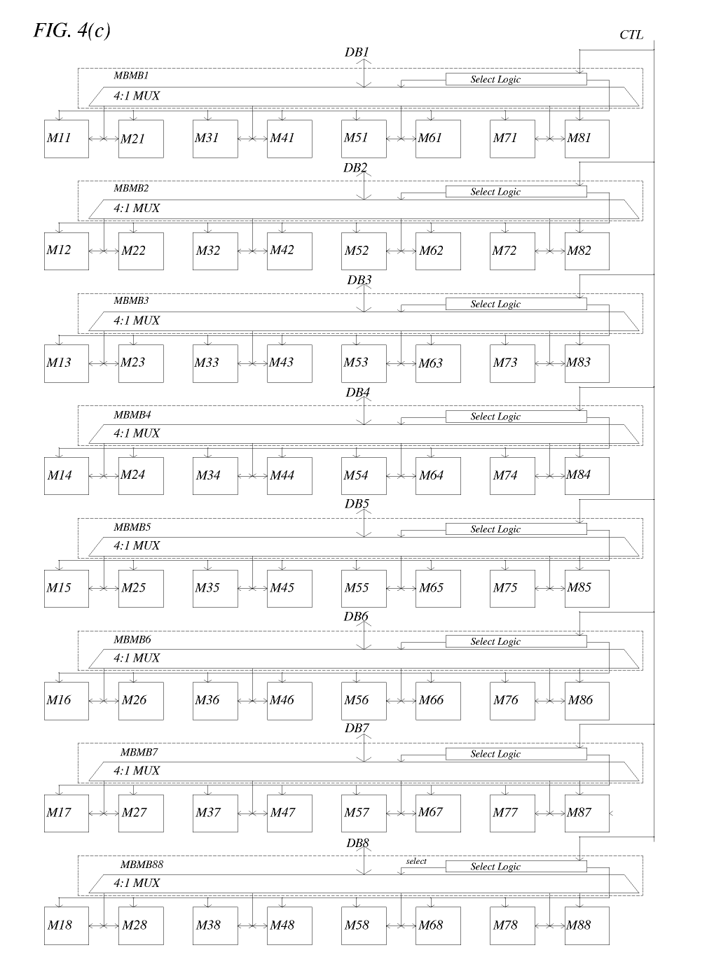

While specific embodiments of the invention have been illustrated and described herein, it is realized that other modifications and changes will occur to those skilled in the art. Upon disclosure of the present invention, those skilled in the art will be able to develop wide varieties of circuits to implement the elements of the present invention. For example, there are many ways in designing the bidirectional multiplexer and supporting selection logic circuits. For another example, the chip select signals connected to memory chips in the same MMB group can be defined in many different ways. If each memory chip in the same MMB group has separated chip select signal, then the function of an MMB system is equivalent to the function of many conventional modules. If all the memory chips in the same MMB group are connected to the same chip select signal, then the function of a MMB group is equivalent to a memory chip of the combined capacity of all memory chips in the group. We certainly can use combinations of the above two chip selection methods. For another example, we can modify the data signal connection methods to define a variation of the MMB architecture called “Multiplexed Bus Memory Buffer” (MBMB) architecture as illustrated by FIGS. 4(a-c).

For the MMB example in FIG. 3(a), each entry of a bidirectional multiplexer is connected to a single memory chip. For MBMB modules, each entry of a bidirectional multiplexer can be shared by multiple memory chips. The MBMB example in FIG. 4(a) illustrates the option when each entry of a multiplexer is shared by two memory chips. Memory chips M11 and M21 are sharing the same data signals (D121) in a bus structure, memory chips M31 and M41 are sharing another set of data signals (D341) in a bus structure, Memory chips M51 and M61 are sharing the same data signals (D561) in a bus structure, while memory chips M71 and M81 are sharing another set of data signals (D781) in a bus structure. Using such configuration, we only need 4-entry bidirectional multiplexers (MUX4) instead of 8-entry bidirectional multiplexers. FIG. 4(b) shows one of the simplest implementation of bidirectional multiplexer useful for applications of the present invention. For this example, the shared data entries (D121, D341, D561, D781 ) are connected to the sources of MOS transistors (M12, M34, M56, M78), while the drains of those transistors are all connected to the same system level data signal (DB1). By controlling the gate signals (G12, G34, G56, G78) we can select chip level signals that are allowed to communicate with the system level signal, and isolate the loadings on unselected signals.

FIG. 4(c) is the simplified schematic block diagram for an MBMB memory system that has the same capacity as the prior art memory system in FIG. 1(c). In this example, the memory system comprises 8 MBMB modules (MBMB1-MBMB8). Each MBMB module comprises 8 memory chips. Each MBMB is equipped with four-entry bidirectional multiplexers to select one set of data signals from one of the eight memory chips in the same MBMB module (with the helps of chip select signals that are not shown separately), while every pair of memory chips share one entry of the MBMB bidirectional multiplexer. The MBMB system in FIG. 4(c) can serve the same function as the prior art system in FIG. 1(c) as well as the MMB system in FIG. 3(c). The signal loadings of the MBMB system are equivalent to that of two memory modules in FIG. 1(b), which is higher than the loading of the MMB system in FIG. 3(a). In the mean time, MBMB modules are more cost efficient than MMB modules due to less entries in bidirectional multiplexers and lower pin counts in MMB chips. The optimum selection is determined by system requirements.

While specific embodiments of the invention have been illustrated and described herein, it is realized that other modifications and changes will occur to those skilled in the art. For example, each entry of MBMB multiplexer certainly can support more than 2 memory chips by trading higher loading to achieve lower costs. Different number of memory chips can be connected to different entries of multiplexers. The number of branch entries of each bidirectional multiplexer can be any number larger or equal to 2, not limited to 4 or 8 entries. We certainly can connect more modules to the MMB or MBMB systems. It is also possible to link MMB or MBMB modules with FBDIMM architectures to achieve very large capacity.

The above discussions showed system/module level architectures. In the following discussions, we will focus on one data signal in the memory systems.

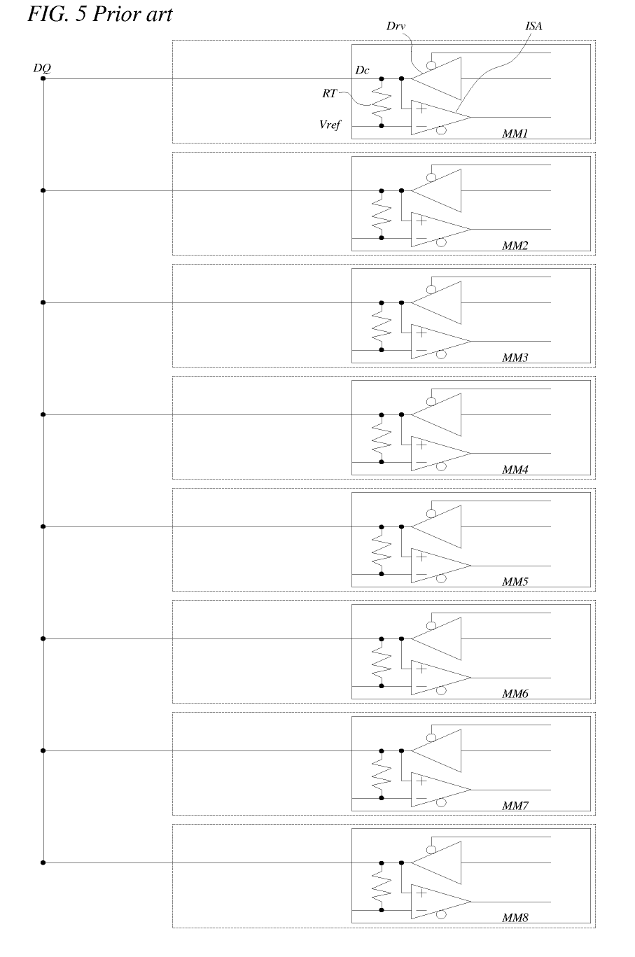

FIG. 5 is a schematic diagram illustrating the circuits connected to one system level data signal (DQ) in a prior art system that has 8 memory chips (MM1-MM8) connected in prior art shared data bus structure. A chip level data signal (Dc) in a memory chip (MM1) is typically connected to the output of an output driver (Drv), the input of an input sense circuit (ISA), and a termination resistor (RT). Typically a limiting resistor is connected between the chip level data signal (Dc) and the system level data signal (DQ); we do not show the limiting resistor for simplicity. The output driver (Drv) is typically a tri-stated driver that is enabled only when the memory chip (MM1) is driving data into DQ. The system control logic assures that at any given time no more than one driver in all the memory chips (MM1-MM8) connected to the same data signal (DQ) is allowed to drive. The input sense circuit (ISA) typically compares the voltage on Dc with a reference voltage (Vref) to determine input data values. DDR2 DRAM is equipped with a termination resistor (RT) for each data signal (Dc) that can be enabled by control logic. The actual implementations are typically more complex than the single resistor shown in our simplified examples. These circuits (Drv, ISA, RT), as well as other supporting circuits such as electrostatic discharge (ESD) protection circuits, bounding pads, packages, etc, increases the loading on each memory chip. For the prior art system in FIG. 5, the loading on the system level data signal (DQ) is the summation of the loadings of all the memory chips (MM1-MM8) and memory modules connected to DQ. Such heavy loading limits the achievable capacity of high performance memory systems.

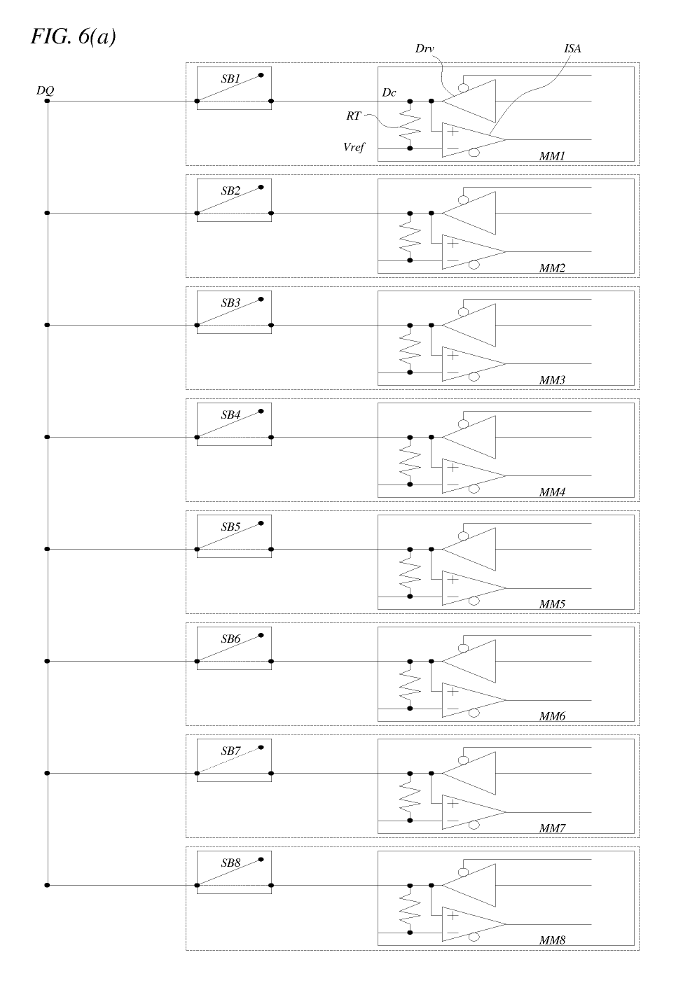

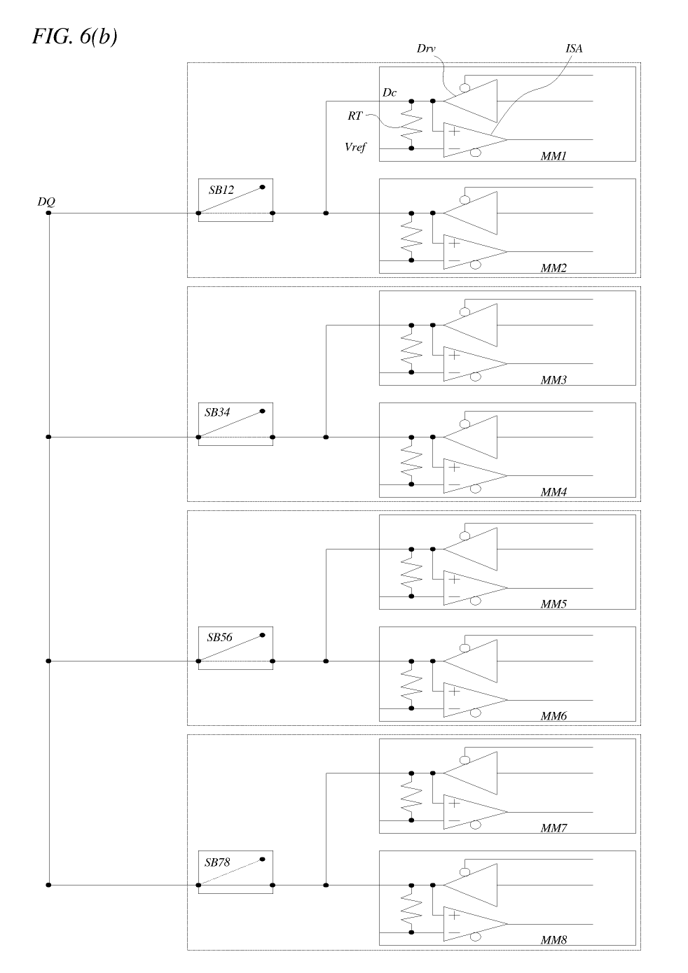

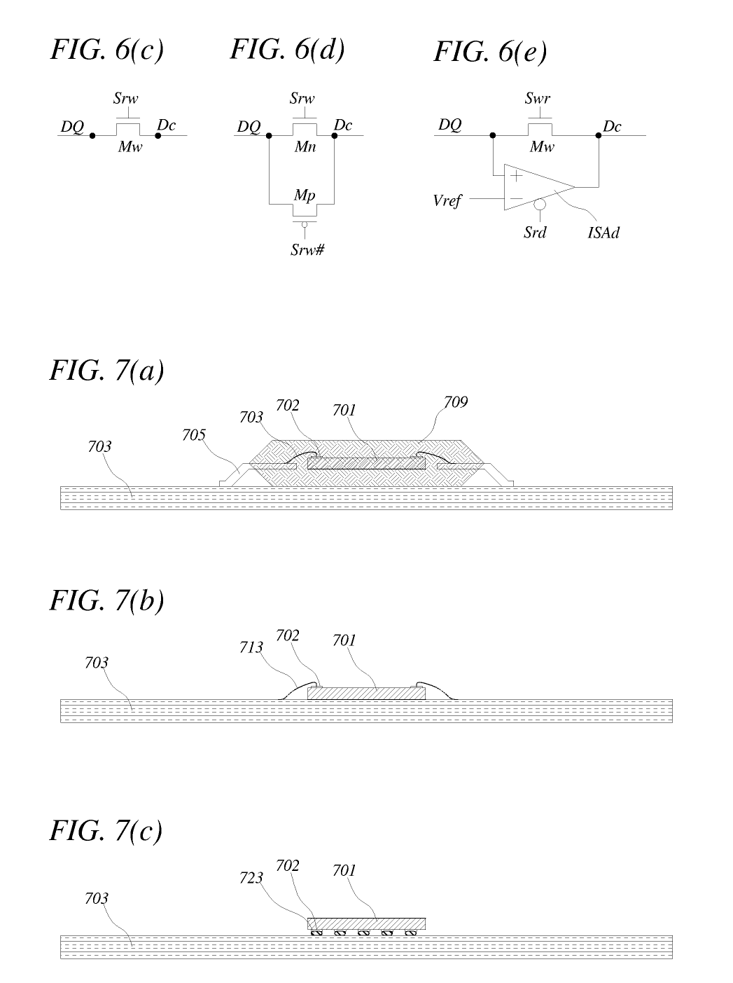

FIG. 6(a) is a schematic diagram illustrating the circuits connected to one system level data signal (DQ) in an MMB system of the present invention that has the same memory chips (MM1-MM8) as the prior art example shown in FIG. 5. The chip level data signal (Dc) is connected to a branch entry of a bidirectional multiplexer (BM1), while the root entry is connected to DQ. In this symbolic example, each branch entry is separated from the root entry by switches (SB1-SB8). When a switch (SB1) is turned on, the attached memory chip (MM11) can access (read or write) data from the system level signal (DQ). Typically the on-impedance of the branch switch (SB1) is designed to be about equal to the impedance of limiting resistors so that we no longer need to use limiting resistors. However, it is still an option to use separated limiting resistors. When a branch switch (SB1) is turned off, the loadings on the chip level signal (Dc) are isolated from the system level signal (DQ). At normal operation conditions, no more than one of the memory chips (MM1-MM8) needs to access DQ so that typically no more than one of the branch switches (SB1-SB8) is on. That means, at normal operation conditions, the loading on DQ is equivalent to the loadings of a single memory chip plus the overhead loadings of the bidirectional multiplexer. The loadings on the system level data signal (DQ) are therefore much less than the loadings of the prior art system shown in FIGS. 5, removing the limits to increase the capacity of high performance memory systems. The major function of the bidirectional multiplexer (BM1) used by the present invention is loading isolation. The logic functions of the drivers (Drv) in memory chips configured in prior art bus structures shown in FIGS. 5 also support the functions of a bidirectional multiplexer but that provides no loading isolation so we do not consider that as a bidirectional multiplexer defined in the present invention. Loading isolation for the purpose of capacity improvement is the key feature of the present invention.

FIG. 6(b) is a schematic diagram illustrating the circuits connected to one system level data signal (DQ) in an MBMB system of the present invention that has the same memory chips (MM1-MM8) as the prior art example shown in FIG. 5. This example is similar to the MMB example shown in FIG. 6(a) except that the memory chips (MM1-MM8) are grouped into pairs. Each pair of memory chips share the same branch entry of a bidirectional multiplexer (BM2). In this symbolic example, each branch entry is separated from the root entry by switches (SB12, SB34, SB56, SB78). When a switch (SB12) is turned on, the attached memory chips (MM1, MM2) can access data from the system level signal (DQ). When a branch switch (SB12) is turned off, the loadings on the chips (MM1, MM2) are isolated from the system level signal (DQ). The loading on DQ is equivalent to the loadings of a pair of memory chips plus the overhead loadings of the bidirectional multiplexer. The loadings on the system level data signal (DQ) are therefore much less than the loadings of the prior art system shown in FIG. 5, removing the limits to increase the capacity of high performance memory systems.

While specific embodiments of the invention have been illustrated and described herein, it is realized that other modifications and changes will occur to those skilled in the art. For example, the bidirectional multiplexer can be placed into an IC chip or separated into multiple chips. The memory chips supporting the same system level data signal can be placed into the same printed circuit board or placed at different printed circuit boards. It is even possible to place branch switches inside of memory chips. If all the branch switches of the same bidirectional multiplexer are placed into the same IC chip, typically we can achieve lower loading. If each branch is placed in a different IC chip at different printed circuit board, the overall loading maybe higher while it is easier to make the resulting PCB fully compatible with prior art modules. Upon disclosure of the present invention, a person with ordinary skill in the art would be able to design many different types of circuits to support implementations of the present invention. For example, FIGS. 6(c-e) illustrate different circuits that support the functions of a branch switch used by the present invention. FIG. 6(c) shows an example when a single transistor (Mw) is used as a branch select switch. The drain of the transistor is connected to system level data signal DQ, the source is connected to chip level data signal Dc, while gate is controlled by a select signal Srw. Typically this transistor is a depletion mode transistor, a native transistor, or an enhanced mode transistor with low threshold voltage. FIG. 6(d) shows an example when a pair of transistors comprising an n-channel transistor (Mn) and a p-channel transistor (MP) are used as a branch select switch. The drains of the transistors are connected to system level data signal DQ, the sources are connected to chip level data signal Dc, while the gate of the n-channel transistor is controlled by the select signal Srw, and the gate of the p-channel transistor is controlled by an inverted select signal Srw#. FIG. 6(e) shows an example when a transistor (Mw) and a sensor/driver (ISAd) are used as the equivalent circuit of a branch select switch. The drain of the transistor is connected to system level data signal DQ, the source is connected to chip level data signal Dc, while the gate is controlled to select signal Swr that is turned on only when the attached memory chip(s) need to drive data. The input of ISAd is connected to system level data signal DQ, the output of ISAd is connected to chip level data signal Dc, while it is controlled by an enable signal (Srd). This sensor/driver (ISAd) is activated only when the attached memory chip(s) need to read data. There are certainly many other ways to implement elements of the bidirectional multiplexer. The scope of the present invention should not be limited by detailed circuit designs.

As discussed previously, the data signal loadings of an MMB system are about the same as that of a single prior art SIMM or DIMM plus overhead. Reducing loading overhead is therefore a major consideration in implementing the present invention. One of the major sources of such overhead is IC package loadings. FIG. 7(a) is a simplified cross section diagram illustrating the structures of a packaged integrated circuit (IC) chip mounted on a printed circuit board. An IC (701) is placed inside a package (709) that is mounted on a printed circuit board (703). To connect a signal from the IC (701) we need to use a bounding wire (702) that connects a bounding pad (702) on the IC to a pin (705) on the package for connection to the printed circuit board (703). Features in our figures are not necessarily drawn to dimension. The impedances (including inductance, capacitance, and resistance) of the bonding wire (703) and package pin (705) introduce significant portions of the loading overhead. On effective method to reduce such overhead is to use the Chip On Board (COB) technologies that mount bare IC on printed circuit board without packaging. One example of COB is illustrated by the simplified cross section diagram in FIG. 7(b). The IC (701) is mounted directed on PCB (703) without using IC package (709). Signal connection is formed by bounding wire (713) that connects bounding pad (702) directly to traces on printed circuit board (703). In this way, the package pin (including lead frame) loading is removed. FIG. 7(c) illustrates another method. In this example, the IC (701) is mounted face down, connecting to the printed circuit board (703) by small soldering balls (723). In this way, the loadings on bounding wire are also removed. These types of COB technologies typically called Flipped Chip On Board (FCOB) technologies. In recent years, IC industry has developed different variations of COB technologies for applications such as mobile phones and flat panel displays. Using COB technologies for the present invention is very effective in reducing the overhead loadings not only for data signals but also for control signals. For example, using COB technologies to mount the register chips that were developed for RDIMM is very helpful in increasing achievable signal rate. It is therefore a good practice to use COB technologies to support the bidirectional multiplexers for data signals as well as the buffers or latches for control signals.

While specific embodiments of the invention have been illustrated and described herein, it is realized that other modifications and changes will occur to those skilled in the art. There are wide varieties of COB technologies under development. The scope of the present invention should not be limited on particular implementations.

The present invention is a board level architecture developed to increase the total capacity of memory systems while isolating the loading of data signals by multiplexing. Comparing to prior art memory modules, the loadings of an MMB system of the present invention are equivalent to a prior art SIMM module. The variation of MMB system called MBMB system allows multiple memory chips to share the same entry of a bidirectional multiplexer in a bused connection. When each entry of a bidirectional multiplexer is shared by two memory chips, the equivalent loadings are about the same as a prior art DIMM module. Using MMB or MBMB architectures, we can achieve memory capacity much higher than prior art memory systems without significant degradation in system performance. The memory systems of the present invention can be fully compatible with prior art memory systems. The costs of MMB or MBMB systems are by far lower than the costs of prior art FBDIMM systems.

Prior art memory systems typically fit one memory module into one printed circuit board. That is not necessary the case for memory modules of the present invention. We often fit multiple modules into a single printed circuit board. A memory module of the present invention also can be placed in multiple printed circuit boards (for example, one branch entry in one PCB). It is also possible to fit the whole memory system into a single printed circuit board. The memory systems of the present invention can have identical system level interface as prior art systems. It is therefore possible to design printed circuit boards of the present invention that can use existing DIMM sockets with no or minimal modifications. The printed circuit boards of the present invention sometimes do not use all the interface signals on a conventional DIMM socket, and sometimes we may need more signals such as chip select signals and clock enable signals in other sockets. We may need to use additional board level connectors or small modifications in board interface to design circuit boards of the present invention that fit into prior art DIMM sockets.

A “memory system” is defined as board level circuits supporting memory operations. A “memory module” is defined as sub circuits of a memory system. A “system level signal” is defined as an electrical signal used to communicate with circuits external to a memory system. A “chip level signal” is defined as an electrical signal used to communicate with memory chips. The “Loading” on a signal is the non-ideal factors that can slow down performances such as leakage currents, parasitic capacitances, inductances, resistances, or termination resistors. A “bidirectional multiplexer” defined in the present invention is a circuitry that provides multiplexing as well as de-multiplexing functions for bidirectional signal communication; A “bidirectional multiplexer” has one “root entry” and a plurality of “branch entries”; During normal operation conditions, one or no branch entry of a bidirectional multiplexer is selected to communicate with the “root entry” while the loadings of unselected branch entries are isolated from the root entry; However “bidirectional multiplexer” allows exceptions, such as transitional operations or special mode operations, to have conditions when multiple branch entries are selected simultaneously. “Isolate loadings from a signal” means significantly reduce the effective loading caused by the signal. Different branch entries of a bidirectional multiplexer used by the present invention can be placed in the same chip, separated into different chips, placed on the same printed circuit board, or placed in different printed circuit boards. The scopes of the present invention should not be limited on detailed implementations of the branch entries of the bidirectional multiplexer. An “IC chip” is defined as packaged integrated circuit or integrated circuit bare die that is ready to be placed on printed circuit board. A “memory chip” is defined as packaged IC memories or bare die memory integrated circuit that is ready to be placed on printed circuit board. COB technologies are technologies that form connections between printed circuit boards to bare IC dice without package. FCOB technologies are variations of COB technologies that form connections between printed circuit boards to bare IC dice without using bounding wires.

While specific embodiments of the invention have been illustrated and described herein, it is realized that other modifications and changes will occur to those skilled in the art. It is therefore to be understood that the appended claims are intended to cover all modifications and changes as fall within the true spirit and scope of the invention.

What is claimed is:

1. A memory system or a memory module comprising:
A plurality of integrated circuit memory chips placed on printed circuit boards;
System level data signals for data communication to circuits external to said memory system or memory module;
Chip level data signals for data communication to said memory chips;
Integrated circuit chip(s) comprising a plurality of bidirectional multiplexers;
Wherein a plurality of system level data signals are connected to the root entries of said bidirectional multiplexers, while the chip level data signals supporting said system level data signals are connected to the branch entries of said bidirectional multiplexers for selective isolation of loadings in which chips comprising said bidirectional multiplexers are bounded to printed circuit board(s) using COB technology.

2. The memory chips in claim 1 are dynamic random access memory chips.

3. The dynamic random access memory chips in claim 2 are synchronized dynamic random access memory integrated circuit with data transfer rate higher than 600 million bits per second per signal.

4. The dynamic random access memory chips in claim 2 supports double data rate operations.

5. The memory system in claim 1 is compatible with JEDEC standard DIMM interface with no or minimal modifications.

6. The COB technology in claim 1 is an FCOB technology that does not use bounding wires.

7. The branch entries of a bidirectional multiplexer in claim 1 are placed in the same IC chip.

8. The branch entries of a bidirectional multiplexer in claim 1 are placed in different IC chips.

9. A method for manufacturing a memory system or a memory module comprising the steps of:
Placing a plurality of integrated circuit memory chips on printed circuit board(s);
Providing system level data signals for data communication to circuits external to said memory system or memory module;
Providing chip level data signals for data communication to said memory chips;
Providing integrated circuit chip(s) comprising a plurality of bidirectional multiplexers;
Wherein a plurality of system level data signals are connected to the root entries of said bidirectional multiplexers, while the chip level data signals supporting said system level data signals are connected to the branch entries of said bidirectional multiplexers for selective isolation of loadings in which chips comprising said bidirectional multiplexers are bounded to printed circuit board(s) using COB technology.

10. The method in claim 9 comprising the step of placing a plurality of memory chips on printed circuit board(s) using dynamic random access memory chips.

11. The method in claim 10 comprising the step of placing a plurality of dynamic random access memory chips on printed circuit board(s) using synchronized dynamic random access memory with data transfer rate higher than 600 million bits per second per signal.

12. The method in claim 9 comprising the step of placing a plurality of dynamic random access memory chips on printed circuit board(s) using dynamic random access memory chips that supports double data rate operations.

13. The method in claim 9 provides a memory system that is compatible with JEDEC standard DIMM interface with no or minimal modifications.

14. The method in claim 9 uses an FCOB technology that does not use bounding wires.

15. The method in claim 9 comprises the step of placing the branch entries of a bidirectional multiplexer in the same IC chip.

16. The method in claim 9 comprises the step of placing the branch entries of a bidirectional multiplexer in different IC chips.

17. A method for manufacturing a memory system or a memory module comprising the steps of:
Placing a plurality of integrated circuit memory chips on printed circuit board(s);
Providing system level control signals for external control to said memory system or memory module;
Providing chip level control signals for controlling operations of said memory chips;
Providing control IC chip(s) comprising buffers or latches that uses said system level control signals to generate said chip level control signals;
Wherein COB technologies are used to form connections between said control IC chip(s) and printed circuit board(s).

18. The method in claim 9 uses an FCOB technology that does not use bounding wires.
